(19) United States
(12) Patent Application Publication
(10) Pub. No.: US 2026/0344120 A1
(43) Pub. Date: Oct. 29, 2026

(54) CHLORINE BASED ISOTROPIC SURFACE TREATMENT OF PLASMA ETCHED SIDE SURFACES OF A µ-LED

(71) Applicant: ams-OSRAM International GmbH, Regensburg (DE)

(72) Inventors: Florian Voegl, Regensburg (DE); Adrian Avramescu, Regensburg (DE); Christian Rumbolz, Lappersdorf (DE); Veronika Heinl, Regensburg (DE); Oleksiy Filipov, Wörth a.d. Isar (DE); Andreas Lex, Zandt (DE)

(21) Appl. No.: 19/486,304

(22) PCT Filed: May 22, 2024
(86) PCT No.: PCT/EP2024/064144

§ 371 Date: Nov. 20, 2025

(30) Foreign Application Priority Data
May 25, 2023 (DE) 10 2023 113 825.1

(51) Int. Cl. H10H 20/819; H10H 20/01

(52) U.S. Cl. CPC H10H 20/819; H10H 20/0137

(57) ABSTRACT

In an embodiment a method includes providing a semiconductor layer stack of at least a first layer of a first conductivity type, a second layer of a second conductivity type and an active region between the first and second layer, plasma etching the semiconductor layer stack, and surface treating etched side surface using a chlorine based substantially isotropic etching process, wherein surface treating includes initiating a reaction of a corrosive component with surface atoms of the etched side surface and removing the corroded surface atoms, and wherein initiating includes an oxidation of the surface atoms of the etched side surface.

### CROSS-REFERENCE TO RELATED APPLICATIONS

This patent application is a national phase filing under section 371 of PCT/EP2024/064144, filed May 22, 2024, which claims the priority of German patent application no. 10 2023 113 825.1, filed May 25, 2023, each of which is incorporated herein by reference in its entirety.

### TECHNICAL FIELD

The present invention concerns a method for manufacturing an optoelectronic device comprising a surface treatment of plasma etched side surface(s) of the optoelectronic device using a chlorine based isotropic etching process as well as an optoelectronic device.

### BACKGROUND

In order to increase the external quantum efficiency (EQE) of for example μ-LEDs, or more general light emitting nanostructures, one can engineer the geometry, shape and surroundings (passivation, reflective mirror, . . . ) of the μ-LEDs in a way that the light extraction efficiency (LEE) in a specific solid angle is maximized. Apart from the LEE the internal quantum efficiency (IQE) is as important, where a main loss factor originates from non-radiative recombination of charge carriers on sidewalls and crystal surface defects of the u-LED.

Plasma etching is a common and standard process for etching LEDs or μ-LEDs (etching through the active region and physical separation of individual LEDs/μ-LEDs) but introduces plasma damage to the surface and underlying layers dependent on the specific process and parameters used. Plasma damage in this case means the creation of defect centres in the crystal lattice caused by Ion bombardment. Especially for small LEDs such as for the case of μ-LEDs with a high surface-to-volume ratio, in particular a high ratio of the exposed active region surface on the μ-LED's sidewall vs. the total active region volume, this is a major challenge. Defects created on the surface and below of the active region-which is exposed during and after etching-act as non-radiative recombination channels and dramatically reduce the IQE of the μ-LED leading to a bad overall performance.

The same applies to laser devices such as vertical-cavity surface-emitting lasers (VCSEL) and edge-emitting lasers. They also face a high surface-to-volume ratio. In addition to μ-LEDs, some of the etched side surfaces of the lasers are within the light path of the light to be emitted and therefor have to be optically perfect. This can mean that the etched side surface(s) need to comprise a lower/no absorption resulting in higher COD-levels.

A common approach to remove plasma damage is a subsequent so-called defect etching step, where defects are reduced or even removed while not creating new defects. Therefore, usually wet chemistry is used, mostly aqueous KOH. The KOH wet etching behaviour of GaN is highly anisotropic due to the different etch rates in different crystallographic directions. Therefore, by starting from a certain μ-LED shape formed by plasma etching e.g., with inclined and smooth side surfaces, the defect etching will change the shape of the μ-LED completely. This includes the formation of micro crystal facets with different orientations (surface patterning) as well as the loss of the overall shape and/or the smoothness. Smooth vertical sidewalls can be etched with KOH for long etching times due to the specific crystal plane etching selectivity, however it is not possible to preserve at the same time inclined side surfaces with a smooth surface.

### SUMMARY

Embodiments provide a method for manufacturing an optoelectronic device and μ-LED in particular, by which a plasma etched shape of the optoelectronic device can be surface treated to remove defects on and below etched side surfaces while keeping the shape and the smoothness of the side surfaces. Embodiments further provide an optoelectronic device and in particular μ-LED with a high IQE as well as a desired shape and smoothness of the side surfaces.

To keep the smooth surface and shape, where for example a later reflective mirror can be deposited, a substantially isotropic process is required which allows to reduce non-radiative recombination on plasma etched side surface(s) of an optoelectronic device and in particular of the active region of the optoelectronic device. At the same time the etched surface shall by such an isotropic process to be kept smooth while keeping the overall shape of the optoelectronic device. Such an isotropic etching process reducing non-radiative recombination channels on or below plasma etched side surface(s) of an optoelectronic device can be provided by using chlorine based isotropic techniques for etching and surface treatment as an alternative to KOH defect etching to reduce non-radiative recombination channels on the side surface(s). In particular low-damage O₂/BCl₃ plasma cycles (e.g., Atomic Layer Etching) or/and wet chemical treatment based on chloride ions e.g., concentrated HCl, iron(III) chloride, or other halogenated solutions can provide such an isotropic etching process reducing non-radiative recombination channels on or below plasma etched side surface(s) of an optoelectronic device.

In a first embodiment, a method for manufacturing an optoelectronic device is provided. The method comprises the steps:
providing a semiconductor layer stack of at least a first layer of a first conductivity type, a second layer of a second conductivity type as well as an active region between the first and second layer;
plasma etching the semiconductor layer stack such that at least a first portion of the semiconductor layer stack is retained and at least a second portion of the semiconductor layer stack adjacent to the first portion is removed, thereby forming an etched side surface of the first portion comprising the first layer, the second layer and the active region; and
surface treating the etched side surface using a chlorine or halogen based substantially isotropic etching process.

The step of surface treating the etched side surface can for example comprise or be an atomic layer etching step. Atomic layer etching (ALE) is a technique in semiconductor manufacture, in which a sequence alternating between self-limiting chemical modification steps, which affect only the top atomic layer(s) of the semiconductor material, and etching steps, which remove only the chemically-modified areas, and allows the removal of individual atomic layers. An example is etching of silicon by alternating reaction with chlorine and etching with argon ions. Compared to reactive ion etching ALE is a process by which the amount of removed semiconductor material can be better controlled, as well as it can be tuned to be a substantially isotropic etching process which propagates in all directions substantially equally. The principle of one possible ALE process is firstly to oxidize an exposed surface, which is a self-limited process. The obtained oxidized layer is then removed in a second step by e.g., chlorine chemistry, which is also self-limited by the amount of oxidized atoms.

Different ALE processes can be:
repeating cycles of O₂ plasma (oxidation) and BCl₃ or Cl₂ plasma (removal) where one or more single atom layers are removed (e.g., Atomic Layer Etching as extreme case);
repeating cycles of wet chemistry using two chemicals, one for oxidation and one for removing of the oxidized layer;
repeating cycles of Plasma and Wet chemistry e.g., O₂ plasma for oxidation and HCl for removing the oxidized layer.

The step of plasma etching the semiconductor layer stack such that at least a first portion of the semiconductor layer stack is retained and at least a second portion of the semiconductor layer stack adjacent to the first portion is removed can for example be a conventional process of pixelation via conventional stepper lithography and plasma etching processes. In particular the first portion can relate to a later optoelectronic device separated out of the semiconductor layer stack.

By means of the plasma etching not only one optoelectronic device can be manufactured but a plurality of optoelectronic devices can be manufactured by retaining a plurality of first portions of the semiconductor layer stack and removing respective second portion(s) between the first portions resulting in a plurality of etched side surfaces. These plurality of etched side surfaces can all at the same time or successively be surface treated in accordance with some of the proposed embodiments.

In some embodiments, the step of surface treating comprises a first step of initiating a reaction of a corrosive component with surface atoms of the etched side surface and a second step of removing the corroded surface atoms. The step of surface treating can thus for example be a two-step process, one of the steps being a step of initiating a reaction of a corrosive component with surface atoms of the etched side surface and the other step being a step of removing the corroded surface atoms. The number of steps is however to be understood as exemplary and the steps of surface treating can also comprise more than two (sub-)steps or only one step.

In some embodiments, the first step comprises an oxidation of the surface atoms of the etched side surface, in particular using oxygen or an oxygen containing component. The oxidation can in particular be initiated using plasma or using a wet chemical and can affect one or several atomic layers. Examples for such an oxygen containing component can be ozone in water, oxygen, an aqueous solution with H₂O₂, ammonium sulphate, BOE, or an aqueous solution of iron hexacyanoferrate.

In some embodiments, the second step comprises an etching step using a chlorine based component, wherein the chlorine based component can for example be HCl, Cl₂ plasma or BCl₃ plasma. Further examples of such a chlorine based component can for example be iron(III)-chloride, or chrome chloride.

In some embodiments, the corrosive component comprises chlorine radicals, which react with surface atoms of the etched side surface and bind in particular with surface atoms of the etched side surface. These chemically modified surface atoms are then removed in the second step.

In some embodiments, the second step comprises a step of plasma exposure of the chemically modified surface atoms with ions. In particular, ions are accelerated in the direction of the etched side surface having a respective ion energy and bombard the etched side surface thereby removing at least some of the chemically modified surface atoms. For example, the step of plasma exposure is conducted using low Ar+-ion energy, in particular in the range between 5 eV to 100 eV. The sputter threshold for the chemically modified surface atoms at the side surface is lower due to the chemical modification in the first step than the sputter threshold of atoms in the bulk material. The Ar+-Ion therefore energy has to be properly adjusted to be below the threshold of the bulk material and above the threshold of the chemically modified atoms.

In some embodiments, the first and second step are repeated a plurality of times in series resulting in a removal of a plurality of atomic layers of the semiconductor layer stack at the etched side surface. The method is thereby not limited to the first and second step be of the same type during repeating them but can also vary between aforementioned different types. For example, the step of surface treating can comprise an oxidation of the surface atoms of the etched side surface using for example oxygen, the oxidized surface atoms can then be removed by means of a chlorine based component, such as for example Cl₂ or BCl₃ plasma. These two steps can be repeated until the desired amount of surface atoms is removed from the semiconductor layer stack at the etched side surface. In addition or as an alternative the step of surface treating can also comprise initiating a reaction of a corrosive component with surface atoms of the etched side surface, wherein the corrosive component comprises chlorine radicals, which react with surface atoms of the etched side surface and bind in particular with surface atoms of the etched side surface. These corroded/bound surface atoms are then for example removed in the second step comprising a step of plasma exposure of the corroded/bound surface atoms with ions. The choice of the corrosive component as well as the etchant/method for removing the corroded surface atoms can thereby vary even within repeating steps and shall not be understood as being limited to one and the same component/etchant/method during surface treating the etched side surface od one and the same optoelectronic device.

In some embodiments, the step of surface treating comprises a treatment of the etched side surface with a halogenated solution, in particular HCl, a chloride-ions containing solution, buffered oxide etch (BOE), or combinations thereof. For example, the step of surface treating can comprise only a treatment of the etched side surface with a halogenated solution or can comprise a treatment of the etched side surface with a halogenated solution in addition to aforementioned two-step process, in particular ALE step. Such a chlorine/halogen-based wet chemistry for surface treatment and defect etching provides no change in shape and roughness, but high improvement in IQE. Test have shown that HCl for example reduces non-radiative recombination for optoelectronic devices with inclined sidewalls and SEM indicates an etching behavior in the order of ~20 nm without micro facets. Thinkable are however also other chlorine-ions containing solutions e.g., Iron(III)-chloride as well as other halogenated solutions e.g., BOE (diluted NH₄F & HF) or a combination of BOE+HCl.

In some embodiments, the semiconductor layer stack and in particular the first and second layer as well as the active region are of a nitride based semiconductor material system. For example, the semiconductor layer stack and in particular the first and second layer as well as the active region are of a gallium nitride (GaN) semiconductor material system. For example, in case of nitride based semiconductor material systems, the creation of non-radiative recombination centres along etched side surface of the optoelectronic device can be very critical. However, the semiconductor layer stack can be of other different Epi structure as well.

In some embodiments, the method further comprises a step of providing a mask in particular structured mask on the semiconductor layer stack covering the first portion of the semiconductor layer stack and exposing the second portion of the semiconductor layer stack for plasma etching the semiconductor layer stack such that at least a first portion of the semiconductor layer stack is retained and at least a second portion of the semiconductor layer stack adjacent to the first portion is removed. The mask can for example be a lithographic etch mask such as for example a photoresist being structured, baked and developed such that it covers the first portion of the semiconductor layer stack and exposes the second portion of the semiconductor layer stack. The mask can for example also be a hard mask, such as for example a mask of SiO₂, Al₂O₃, metal like Ni, or Cr. The mask can for example have different pitches, sizes and shapes (round shaped, square, hexagonal, . . . ).

In some embodiments, a contact layer is arranged on the at least first portion of the semiconductor layer stack, in particular comprising a transparent conductive oxide such as indium tin oxide. The contact layer on the at least first portion of the semiconductor layer stack can for example act as a mask/hard mask on the semiconductor layer stack covering the first portion of the semiconductor layer stack and exposing the second portion of the semiconductor layer stack for plasma etching the semiconductor layer stack such that at least a first portion of the semiconductor layer stack is retained and at least a second portion of the semiconductor layer stack adjacent to the first portion is removed. The contact layer can however also be below aforementioned mask and can during the step of plasma etching the semiconductor layer stack also be structured to only cover the first portion but not the removed second portion.

In some embodiments, the provision of a mask as well as of a contact layer on the at least first portion of the semiconductor layer stack can be a combined process of providing combinations of for example ITO+SiO₂ or a Metal+SiO₂ or any other aforementioned materials in combination. This material combination on the at least first portion of the semiconductor layer stack can for example act as a mask/hard mask on the semiconductor layer stack covering the first portion of the semiconductor layer stack and exposing the second portion of the semiconductor layer stack for plasma etching the semiconductor layer stack such that at least a first portion of the semiconductor layer stack is retained and at least a second portion of the semiconductor layer stack adjacent to the first portion is removed.

In some embodiments, the at least first portion comprises a mesa shaped cross section, a parabolic cross section, or a stepped cross section. By means of the step of plasma etching the semiconductor layer stack the shape of the first portion can for example be defined. The shape of the first portion can for example be designed by tuning the etching parameters of the plasma etching as well as by defining the mask/contact layer on top of the first portion. In addition, shape of the first portion can for example be designed by multiple plasma etching steps with different parameters and/or different masks. Different side surface angles as well as the size of a top and bottom surface of the semiconductor layer stack can for example be controlled by structuring the mask in a desired way (Thickness, Mask size, Exposure, Hardbake, . . . ) , as well as by choosing respective process parameters of the plasma etching (Pressure, gas species, vacuum, power, . . . ). More complex side surface structures can for example be obtained by using a combination of different photo resist masks and a combination of subsequent etching processes.

In another embodiments, an optoelectronic device, in particular optoelectronic device manufactured in accordance with some of aforementioned embodiments. The optoelectronic device comprises a semiconductor layer stack of at least a first layer of a first conductivity type, a second layer of a second conductivity type as well as an active region between the first and second layer. The optoelectronic device further comprises a top contact element arranged on a top surface of the semiconductor layer stack and a bottom contact element arranged on a bottom surface of the semiconductor layer stack. Side surfaces of the semiconductor layer connecting the top and the bottom surface are thereby inclined with respect to the top and/or the bottom surface and in particular enclose an angle between 45° and 85° or between 95° and 135° with respect to each other respectively. In addition, the side surfaces comprise a surface roughness of less than 10 nm and in particular of less than 5 nm. Further the semiconductor layer stack comprises along its side surfaces a defect density that causes a current density along the side surfaces of less than or in in the order of 1e⁻⁴ A/cm² when applying a potential difference of −5V between the top and bottom contact element or that causes a current density along the side surfaces of less than or in in the order of 1e⁻⁴ A/cm² when applying a potential difference of +1V between the top and bottom contact element.

In some embodiments, the semiconductor layer stack and in particular the first and second layer as well as the active region are of a nitride based semiconductor material system such as for example a GaN material system.

In some embodiments, the top and/or bottom contact element comprises a transparent conductive oxide, such as for example indium tin oxide.

The proposed solution works for any nitride based μ-LED shapes or more general light emitting nanostructures etched by plasma with exposed active regions. Also, for laser devices like VCSELs or edge-emitting lasers the solution is very promising, as it could further be used to improve etched facets not only for electrical, but also for optical reasons.

### BRIEF DESCRIPTION OF THE DRAWINGS

Further embodiments will become apparent in relation to the various examples described in detail in connection with the accompanying drawings in which:

FIG. 1 shows steps of a method for manufacturing an optoelectronic device;

FIG. 2 shows steps of a method for manufacturing an optoelectronic device in accordance with some embodiments;

FIGS. 3A to 3L show further steps of a method for manufacturing an optoelectronic device in accordance with some embodiments;

FIGS. 4A and 4B show further steps of a method for manufacturing an optoelectronic device in accordance with some embodiments;

FIGS. 5A and 5B show further steps of a method for manufacturing an optoelectronic device in accordance with some embodiments; and

FIGS. 6A and 6B show further steps of a method for manufacturing an optoelectronic device in accordance with some embodiments.

### DETAILED DESCRIPTION OF ILLUSTRATIVE EMBODIMENTS

The following embodiments and examples disclose various aspects of the present disclosure. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

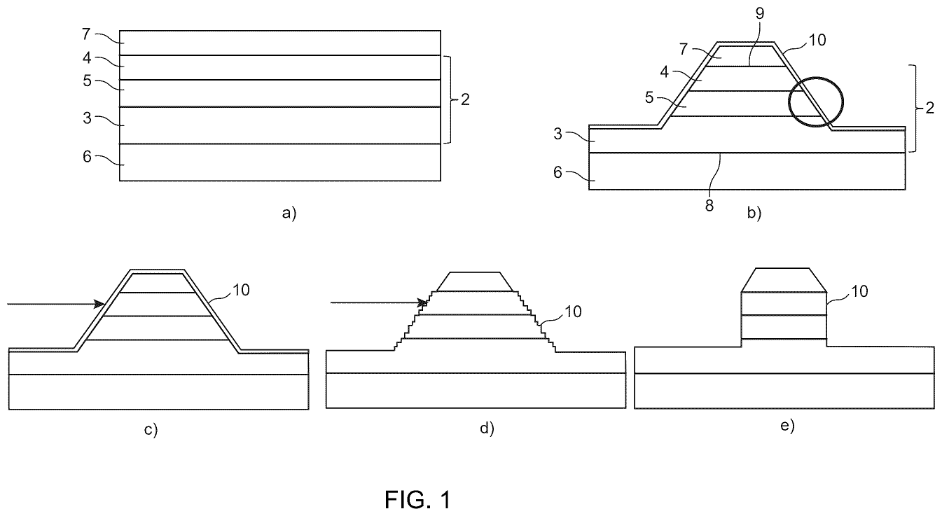

FIG. 1 shows in its subfigures steps of a method for manufacturing an optoelectronic device not according to the proposed principle. As shown in a), in a first step, a semiconductor layer stack 2 of at least a first layer 3 of a first conductivity type, a second layer 4 of a second conductivity type as well as an active region 5 between the first and second layer 3, 4 is provided. The semiconductor layer stack 2 is arranged on a growth substrate 6 and a contact layer 7 of for example ITO is arranged on the semiconductor layer stack 2. The semiconductor layer stack 2 is in a subsequent step pixelated by means of plasma etching as shown in b) resulting in etched side surfaces 10 of the pixelated portion. The plasma etching introduces damage on the side surface 10 and also below the side surface. This in particular in the active region 5, indicated by the circle, is a major problem, since it creates non-radiative recombination channels for charge carriers along the side surface 10 leading to a low EQE of the final optoelectronic device. This effect is less relevant for large structures but is very important to be dealt with for small LEDs with a high surface/volume ratio such as for example μ-LEDs.

Subfigures c) to e) show a conventional defect etching method using KOH to remove the damages introduced by the plasma etching. When KOH is applied to the side surfaces 10, it does remove the damages, however due to the anisotropy etching behaviour of KOH, as indicated by the arrows in c) and d), the treatment with KOH results in micro facets of different crystal planes (see d)) or the side surfaces will be smooth for sufficient long etching time but in turn the inclined side surfaces turns to be vertical (see e)). The etching of the KOH just stops due to the contact layer 7 being of for example of ITO and acting as an etch stop. Thus, KOH defect etching is not possible for μ-LEDs with inclined or any other formed side surfaces, which for some reason must not only be vertical and at the same time smooth to ensure the necessary light outcoupling properties.

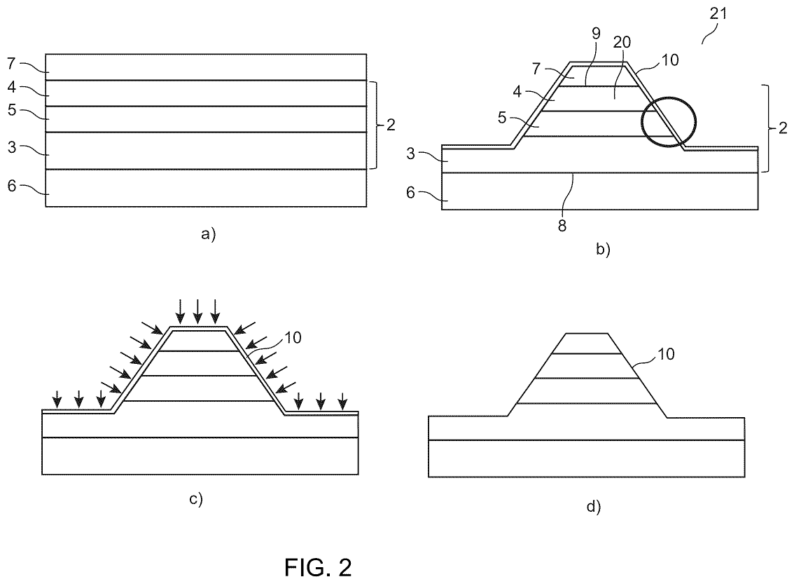

FIG. 2 shows in its subfigure's exemplary steps of a method for manufacturing an optoelectronic device according to some aspects of the proposed principle. As shown in a), in a first step, a semiconductor layer stack 2 of at least a first layer 3 of a first conductivity type, a second layer 4 of a second conductivity type as well as an active region 5 between the first and second layer 3, 4 is provided. The semiconductor layer stack 2 is arranged on a growth substrate 6 and a contact layer 7 of for example ITO is arranged on the semiconductor layer stack 2. The semiconductor layer stack 2 is in a subsequent step pixelated by means of plasma etching as shown in b) resulting in etched side surfaces 10 of a first portion 10 of the semiconductor layer stack 2 when removing an adjacent second portion 21 of the semiconductor layer stack 2. The plasma etching introduces damage on the etched side surfaces 10 and also below the side surfaces 10. This in particular in the active region 5, indicated by the circle, is a major problem, since it creates non-radiative recombination channels for charge carriers along the side surfaces 10 leading to a low EQE of the final optoelectronic device. The contact layer 7 can however also be arranged on the first portion after the step of plasma etching or at an even later point of time and a different material, such as for example a hard mask can be used instead for the step of plasm etching into the semiconductor layer stack 2.

To remove the damages, the etched side surfaces 10 are surface treated as shown in subfigure c), using a chlorine based isotropic etching process. The isotropic etching is indicated by the arrows in subfigure c), showing that a removal of the damage conducts in all directions at the same time. The surface treatment can for example comprise an ALE process and/or a treatment of the etched side surface with a halogenated solution. Due to the properties of the ALE process, the ALE process as well as the treatment of the etched side surface with a halogenated solution removes only atomic layers and in particular atomic layers in all directions such that the shape and smoothness of the first portion 20 is maintained, as showed in subfigure d), even though the damages along and under the side surfaces 10 have been removed. The structure as shown in subfigure d can then in later steps be further processes to receive an optoelectronic device, in particular μ-LED with a high EQE.

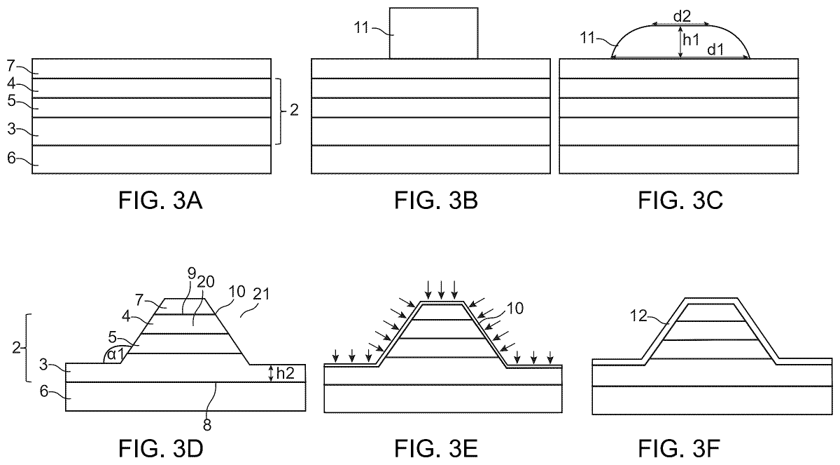

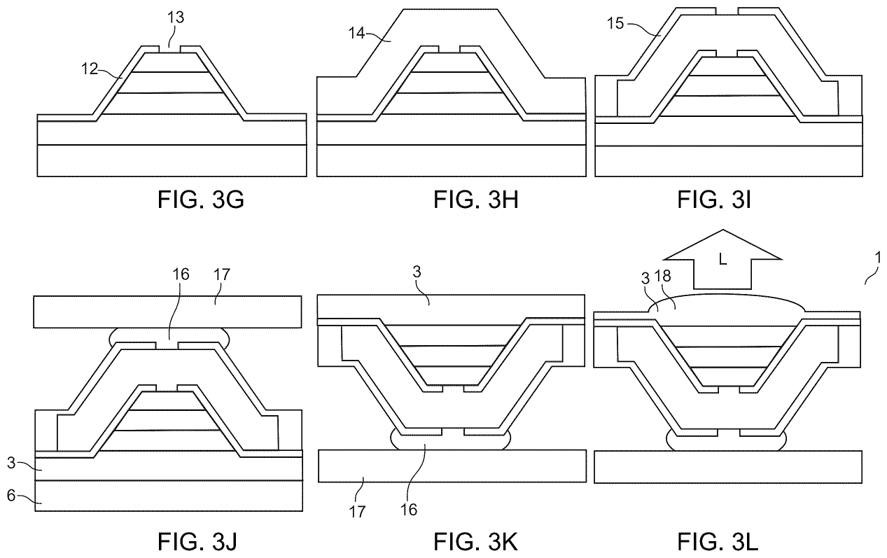

FIGS. 3A to 3L show further steps of a method for manufacturing an optoelectronic device in accordance with some aspects of the proposed principle.

As shown in FIG. 3A, a semiconductor layer stack 2 of at least a first layer 3 of a first conductivity type, a second layer 4 of a second conductivity type as well as an active region 5 between the first and second layer 3, 4 is provided. The semiconductor layer stack 2 is arranged on a growth substrate 6 and a contact layer 7 of for example ITO is arranged on the semiconductor layer stack 2.

As shown in FIG. 3B, a structured photoresist material 7 is arranged on the semiconductor layer stack 2 covering a first portion of the semiconductor layer stack 2 and exposing a second portion of the semiconductor layer stack 2. The structured photoresist material 7 is then in a subsequent step, as shown in FIG. 3C hard baked and developed resulting in a dome-shaped mask 7 above the first portion of the semiconductor layer stack 2 with a height h1, a first width d1 on the semiconductor layer stack 2 and a second width d2 on an opposing side of the mask 7. By means of choosing the baking and developing parameters the shape (h1, d1, d2) can be optimized to introduce a respective angle and a round shape at the edges of the mask, which influences the subsequent plasma etching process to pixelate the semiconductor layer stack 2.

FIG. 3D shows an exemplary resulting structure after plasma etching the semiconductor layer stack 2. By means of the parameters of the plasma etching process as well as the shape of the mask 7, the first portion can comprise a mesa structure with a respective angle α1 between side surfaces 10 and the bottom/top surface 8, 9 of the semiconductor layer stack 2. In addition, by means of the parameters of the plasma etching process the depth of the etching can be tuned resulting in a retaining portion of the first layer with a height h2. The resulting etched side surfaces 10 are due to the plasma etching smooth but contain damages which would lead to non-radiative recombination centres when still present in the final optoelectronic device.

The etched side surfaces 10 are therefore surface treated by means of an isotropic chlorine based etching process, as shown in FIG. 3E, to reduce the non-radiative recombination channels on the surface. The surface treatment can for example comprise an ALE process and/or a treatment of the etched side surface with a halogenated solution in accordance with some aspects of the invention. After the surface treatment, the side surfaces of the first portion remained in their shape, still having a smooth surface structure with a surface roughness of less than 10 nm and in particular less than 5 nm. The structure can then be further processed to end up with optoelectronic components with a high EQE as well as desired optical properties.

FIGS. 3F to 3L show exemplary steps of further processing the structure to end up with optoelectronic components. As shown in FIG. 3F, a passivation/dielectric layer 12 for chemical surface passivation is applied to the side surfaces 10. The passivation layer 12 can be applied by Atomic Layer Deposition or Sputtering, (e.g. ALD Al₂O₃, ALD AlN, SiO₂) with for example a thickness of a single monolayer up to hundreds of nanometers. Also other passivation methods are thinkable like hydrogen passivation, or a combination of Al₂O₃ for chemical passivation and Nb₂O₅ for providing desired optical properties.

As shown in FIG. 3G, the passivation layer 12 is then opened resulting in opening 13, for providing a for example a p-contact for the later optoelectronic device. The opening of the passivation layer for electrical contact to the contact layer 7 can for example comprise a lithography process es well as a wet etching or plasma etching process.

On the passivation layer 12, a metal mirror 14 is deposited electrical contacting the contact layer 7, as shown in FIG. 3H. As an alternative, other reflector or mirror structures/materials are possible e.g., a periodic stack of dielectric materials with different refractive indexes.

The individual first portions are then electrically isolated by means of a dielectric material 15, as shown in FIG. 3I, and in a subsequent step, as shown in FIG. 3J, wafer bonded to a Si substrate such as a backplane 17 by means of solder pads 16. The growth substrate 6 is then removed, as shown in FIG. 3K, and an outcoupling structure 18 for light L emitted by the optoelectronic device 1 is etched into the first layer 3 as shown in FIG. 3L. Any kind of outcoupling structure 18 or combination is thinkable e.g., etching of certain structures like lenses or resonators into the first layer 3 via plasma, or a surface roughening of the bottom surface 8, or the placement of a lens on the bottom surface 8.

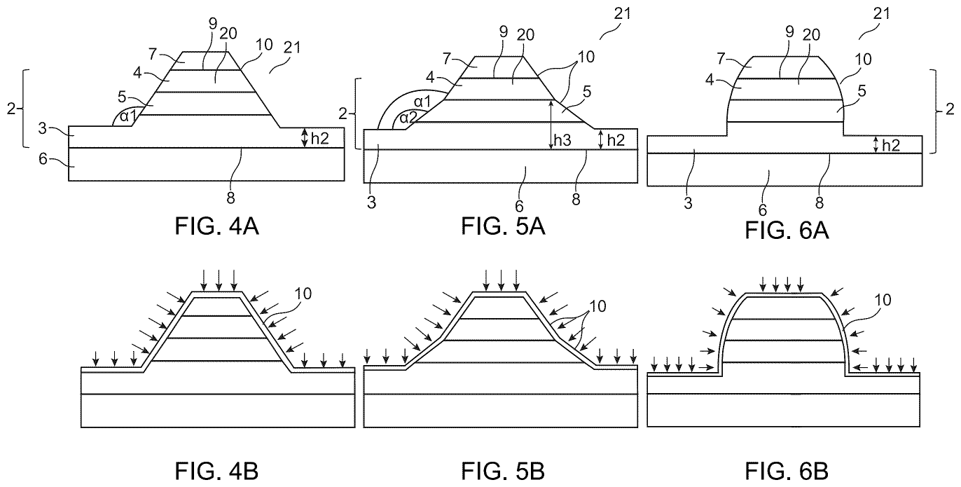

FIGS. 4A and 4B, 5A and 5B and 6A and 6B show some alternatives to the plasma etched shape shown in FIG. 3D as well as a respective isotropic surface treatment of resulting side surfaces 10.

The mask 11 and the subsequent plasma etching process goes hand in hand and need proper coordination and precise iterative tuning. E.g., It is possible to form smooth sidewalls with one or two certain angles a1, a2 as shown in FIGS. 5A and 5B also starting with a spherical photo resist shape as a mask 11.

The plasma parameters can be tuned in a way that a selectivity between the top contact element 7 and the semiconductor layer 4 below is reached. In this way the contact element 7 can in a subsequent plasma etching step serve as a quasi hard mask, once the mask 11 is fully removed and can be used to insert a second angle a2 between the side surface 10 and the top/bottom surface 8, 9. Also nanoimprint lithography or greyscale lithography can be used to form arbitrary shapes in the photoresist 11. It is also possible to use subsequently different etching recipes or using a combination of different resists to obtain more angles until for example reaching the curved/parabolic shape shown in FIGS. 6A and 6B.

The applied surface treatment of the resulting plasma etched side surfaces 10 as proposed by the invention does not substantially change their shape and roughness but removes damages ion and below the side surfaces 10 improving the EQE of the resulting optoelectronic device.

1.-20. (canceled)

21. A method for manufacturing an optoelectronic device, the method comprising:
providing a semiconductor layer stack of at least a first layer of a first conductivity type, a second layer of a second conductivity type and an active region between the first and second layer;
plasma etching the semiconductor layer stack such that at least a first portion of the semiconductor layer stack is retained and at least a second portion of the semiconductor layer stack adjacent to the first portion is removed, thereby forming an etched side surface of the first portion comprising the first layer, the second layer and the active region; and
surface treating the etched side surface using a chlorine based substantially isotropic etching process,
wherein surface treating comprises initiating a reaction of a corrosive component with surface atoms of the etched side surface and removing the corroded surface atoms, and
wherein initiating comprises an oxidation of the surface atoms of the etched side surface.

22. The method according to claim 21, wherein removing comprises etching using a chlorine based component.

23. The method according to claim 22, wherein the chlorine based component is HCl, Cl₂ plasma or BCl₃ plasma.

24. The method according to claim 21, wherein the corrosive component comprises chlorine radicals.

25. The method according to claim 21, wherein removing comprises plasma exposure of corroded surface atoms with ions.

26. The method according to claim 25, wherein the plasma exposure is conducted by low Ar+-ion energy in a range between 5 eV and 100 eV, inclusive.

27. The method according to claim 21, wherein initiating and removing are repeated a plurality of times in series.

28. The method according to claim 21, wherein surface treating comprises atomic layer etching.

29. The method according to claim 21, wherein surface treating comprises a treatment of the etched side surface with HCl, a chloride-ions containing solution, BOE, or a combinations thereof.

30. The method according to claim 21, further comprising providing a mask on the semiconductor layer stack covering the first portion of the semiconductor layer stack and exposing the second portion of the semiconductor layer stack.

31. The method according to claim 21, wherein the semiconductor layer stack is of a nitride based material system.

32. The method according to claim 21, wherein a contact layer is arranged on the first portion of the semiconductor layer stack.

33. The method according to claim 32, wherein the contact layer on the first portion of the semiconductor layer stack acts as a mask on the semiconductor layer stack covering the first portion of the semiconductor layer stack and exposing the second portion of the semiconductor layer stack.

34. The method according to claim 21, wherein the first portion comprises a mesa shaped cross section, a parabolic cross section, or a stepped cross section.

35. An optoelectronic device comprising:
a semiconductor layer stack of at least a first layer of a first conductivity type, a second layer of a second conductivity type and an active region between the first and second layer; and
a top contact element arranged on a top surface of the semiconductor layer stack opposite a bottom surface of the semiconductor layer stack,
wherein side surfaces of the semiconductor layer stack connecting the top surface and the bottom surface are inclined with respect to the top surface and/or the bottom surface,
wherein the side surfaces comprise a surface roughness of less than 10 nm, and
wherein the top contact element comprises a transparent conductive oxide.

36. The optoelectronic device according to claim 35, wherein the semiconductor layer stack comprises a defect density along side surfaces that causes a current density along the side surfaces of less than or in in an order of 1e⁻⁴ A/cm² when applying a potential difference of −5V between the top contact element and a bottom contact element or that causes a current density along the side surfaces of less than or in in the order of 1e⁻⁴ A/cm² when applying a potential difference of +1V between the top and bottom contact elements.

37. The optoelectronic device according to claim 35, wherein the semiconductor layer stack is of a nitride based material system.

38. The optoelectronic device according to claim 35, wherein the bottom contact element comprises a transparent conductive oxide.
